(19) United States
(12) Patent Application Publication
(10) Pub. No.: US 2022/0271507 A1
(43) Pub. Date: Aug. 25, 2022

(54) SURFACE EMITTING LASER DEVICE

(71) Applicant: ROHM CO., LTD., Kyoto (JP)

(72) Inventor: Daiju TAKAMIZU, Kyoto (JP)

(73) Assignee: ROHM CO., LTD., Kyoto (JP)

(21) Appl. No.: 17/581,249

(22) Filed: Jan. 21, 2022

(30) Foreign Application Priority Data
Feb. 22, 2021 (JP) 2021-026212

(51) Int. Cl. H01S 5/183; H01S 5/042

(52) U.S. Cl. CPC H01S 5/18377; H01S 5/04256; H01S 5/04254

(57) ABSTRACT

A surface emitting laser device includes: a first semiconductor layer of a first conductive type; a second semiconductor layer including a first light reflecting layer of the first conductive type, a light generating layer, and a second light reflecting layer of a second conductive type, which are laminated in this order from a first semiconductor layer side; a laser diode structure partitioned in a plateau shape including a top surface by a removal portion in which the second semiconductor layer is dug down, and configured to emit a laser beam to the first semiconductor layer side; a first insulating layer formed inside the laser diode structure; and a second insulating layer covering the top surface.

### CROSS-REFERENCE TO RELATED APPLICATION

This application is based upon and claims the benefit of priority from Japanese Patent Application No. 2021-026212, filed on Feb. 22, 2021, the entire contents of which are incorporated herein by reference.

### TECHNICAL FIELD

The present disclosure relates to a surface emitting laser device.

### BACKGROUND

In the related art, a surface emitting laser element including a columnar structure that emits a laser beam on the side opposite to a substrate is disclosed.

### SUMMARY

Some embodiments of the present disclosure provide a surface emitting laser device having a novel structure.

According to one embodiment of the present disclosure, there is provided a surface emitting laser device including: a first semiconductor layer of a first conductive type; a second semiconductor layer including a first light reflecting layer of the first conductive type, a light generating layer, and a second light reflecting layer of a second conductive type, which are laminated in this order from a first semiconductor layer side; a laser diode structure partitioned in a plateau shape including a top surface by a removal portion in which the second semiconductor layer is dug down, and configured to emit a laser beam to the first semiconductor layer side; a first insulating layer formed inside the laser diode structure, including a first opening having a first diameter in a plan view, and partitioning a current constriction layer by the first opening; and a second insulating layer covering the top surface and including a second opening having a second diameter less than the first diameter in a region surrounded by the first opening in a plan view.

### BRIEF DESCRIPTION OF DRAWINGS

FIG. 1 is a plan view showing a surface emitting laser device according to a first embodiment of the present disclosure.

FIG. 2 is a cross-sectional view taken along line II-II shown in FIG. 1.

FIG. 3 is an enlarged cross-sectional view of a laser diode structure shown in FIG. 2.

FIG. 4 is a plan view showing a package on which the surface emitting laser device shown in FIG. 1 is mounted.

FIG. 5 is a cross-sectional view taken along line V-V shown in FIG. 4.

FIG. 6 corresponds to FIG. 2 and is a cross-sectional view showing a surface emitting laser device according to a second embodiment of the present disclosure.

FIG. 7 corresponds to FIG. 2 and is a cross-sectional view showing a surface emitting laser device according to a third embodiment of the present disclosure.

FIG. 8 corresponds to FIG. 2 and is a cross-sectional view showing a surface emitting laser device according to a fourth embodiment of the present disclosure.

FIG. 9 corresponds to FIG. 2 and is a cross-sectional view showing a surface emitting laser device according to a fifth embodiment of the present disclosure.

FIG. 10 is a plan view showing a surface emitting laser device according to a sixth embodiment of the present disclosure.

FIG. 11 is a cross-sectional view taken along line XI-XI shown in FIG. 10.

FIG. 12 is a plan view showing a modification of the surface emitting laser device according to the first embodiment.

### DETAILED DESCRIPTION

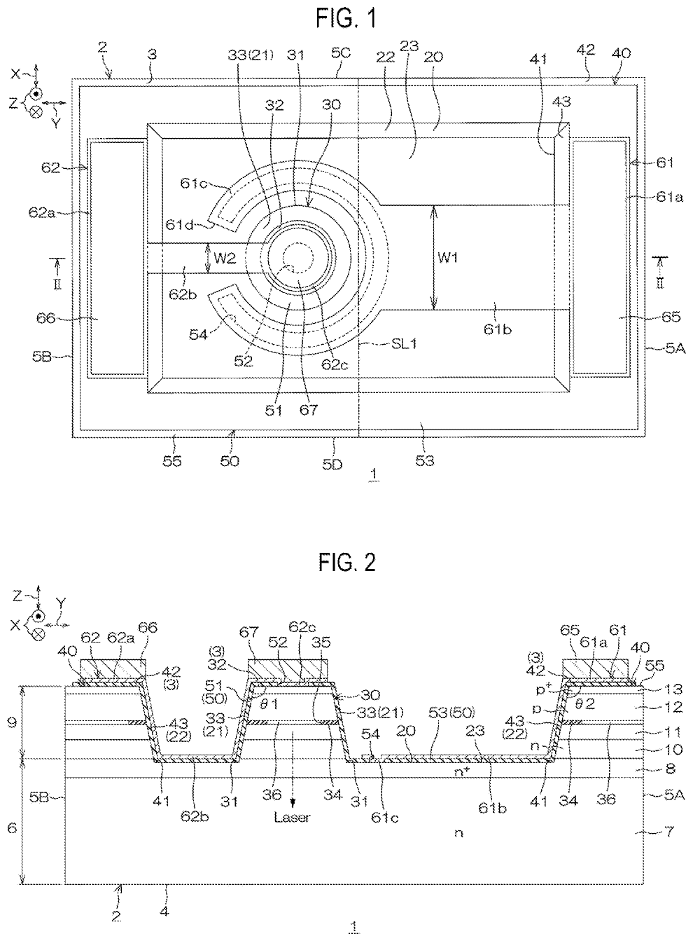

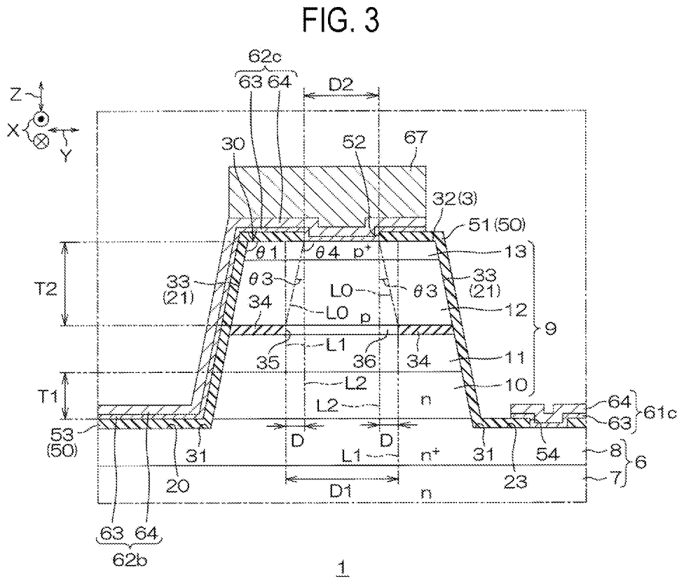

Embodiments of the present disclosure will now be described in detail with reference to the accompanying drawings. The accompanying drawings are schematic and are not exactly illustrated, and the scales thereof and the like do not always match. FIG. 1 is a plan view showing a surface emitting laser device 1 according to a first embodiment of the present disclosure. FIG. 2 is a cross-sectional view taken along line II-II shown in FIG. 1. FIG. 3 is an enlarged cross-sectional view of a laser diode structure 30 shown in FIG. 2.

Referring to FIGS. 1 to 3, the surface emitting laser device 1 is a semiconductor laser device called a VCSEL (Vertical Cavity Surface Emitting Laser) in this embodiment. The surface emitting laser device 1 includes a chip 2 having a hexahedral shape (a rectangular parallelepiped shape in this embodiment). The chip 2 includes a first main surface 3 on one side, a second main surface 4 on the other side, and first to fourth side surfaces 5A to 5D connecting the first main surface 3 and the second main surface 4.

The first main surface 3 is a mounting surface, and the second main surface 4 is a non-mounting surface. The first main surface 3 (mounting surface) is a surface facing a connection target when the surface emitting laser device 1 is connected to the connection target. The second main surface 4 (non-mounting surface) is a light extraction surface exposed to the outside air. That is, the surface emitting laser device 1 does not have a metal film that covers the second main surface 4. The first main surface 3 and the second main surface 4 are formed in a square shape (rectangular shape in this embodiment) in a plan view when viewed from their normal direction Z (hereinafter, simply referred to as a “plan view”).

The first side surface 5A and the second side surface 5B extend in a first direction X along the first main surface 3 and face (opposes) a second direction Y that intersects (specifically, is orthogonal to) the first direction X. The first side surface 5A and the second side surface 5B form the short side of the chip 2. The third side surface 5C and the fourth side surface 5D extend in the second direction Y and face the first direction X. The third side surface 5C and the fourth side surface 5D form the long side of the chip 2.

The surface emitting laser device 1 includes an n-type first semiconductor layer 6 formed on the second main surface 4 side inside the chip 2. The first semiconductor layer 6 forms portions of the second main surface 4 and the first to fourth side surfaces 5A to 5D of the chip 2. The first semiconductor layer 6 is composed of a compound semiconductor single crystal that forms a tetragonal crystal. The first semiconductor layer 6 may be a group III-V semiconductor single crystal. The first semiconductor layer 6 is composed of a GaAs single crystal in this embodiment. A main surface of the first semiconductor layer 6 may face the surface of the GaAs single crystal.

In this embodiment, the first semiconductor layer 6 includes a laminated structure including an n-type semiconductor substrate 7 and an n-type first contact layer 8. The semiconductor substrate 7 is composed of a compound semiconductor substrate (GaAs substrate in this embodiment). The first contact layer 8 is composed of a compound semiconductor epitaxial layer (GaAs epitaxial layer in this embodiment) laminated on a main surface of the semiconductor substrate 7. The first contact layer 8 may have an n-type impurity concentration higher than that of the semiconductor substrate 7. The first contact layer 8 may have an n-type impurity concentration substantially equal to that of the semiconductor substrate 7.

The surface emitting laser device 1 includes a second semiconductor layer 9 formed on a side of the first main surface 3, inside the chip 2. The second semiconductor layer 9 forms portions of the first main surface 3 and the first to fourth side surfaces 5A to 5D of the chip 2. The second semiconductor layer 9 is formed by a plurality of compound semiconductor (III-V group semiconductor) epitaxial layers laminated on the first semiconductor layer 6. The second semiconductor layer 9 includes the same crystal plane as the first semiconductor layer 6.

Specifically, the second semiconductor layer 9 includes an n-type first light reflecting layer 10, a light generating layer 11, a p-type (second conductive type) second light reflecting layer 12, and a p-type second contact layer 13 laminated in this order from the top of the first semiconductor layer 6. The first light reflecting layer 10 is composed of an n-type DBR (Distributed Bragg Reflector) layer, and has an n-type impurity concentration lower than that of the first contact layer 8. The first light reflecting layer 10 has a refractive index that periodically changes in the normal direction Z. The first light reflecting layer 10 includes a laminated structure in which a plurality of Al composition layers having different refractive indexes are laminated.

In this embodiment, the first light reflecting layer 10 includes a laminated structure in which a first AlGaAs layer having a first Al composition and a second AlGaAs layer having a second Al composition less than the first Al composition are alternately laminated with an arbitrary cycle. The lamination cycle of the first AlGaAs layer and the second AlGaAs layer may be 10 or more and 50 or less. The first light reflecting layer 10 has a first thickness T1. The first thickness T1 may be 1 μm or more and 10 μm or less.

The light generating layer 11 includes an MQW (Multi Quantum Well) structure in which a quantum well layer and a barrier layer are alternately laminated with an arbitrary cycle. The lamination cycle of the quantum well layer and the barrier layer may be 1 or more and 50 or less. The quantum well layer may include an impurity-free GaAs layer or InGaAs layer. The barrier layer includes an AlGaAs layer and has a band gap larger than that of the quantum well layer.

The second light reflecting layer 12 is composed of a p-type DBR layer. The second light reflecting layer 12 has a refractive index that periodically changes in the normal direction Z. The second light reflecting layer 12 includes a laminated structure in which a plurality of Al composition layers having different refractive indexes are laminated. In this embodiment, the second light reflecting layer 12 includes a laminated structure in which a third AlGaAs layer having a third Al composition and a fourth AlGaAs layer having a fourth Al composition less than the third Al composition are alternately laminated with an arbitrary cycle. The lamination cycle of the third AlGaAs layer and the fourth AlGaAs layer may be 10 or more and 50 or less. A second thickness T2 may be 1 μm or more and 10 μm or less. The second light reflecting layer 12 may have the second thickness T2 that exceeds the first thickness T1 of the first light reflecting layer 10 (T1<T2).

The second contact layer 13 forms the first main surface 3 of the chip 2. The second contact layer 13 includes a p-type GaAs layer and has a p-type impurity concentration higher than that of the second light reflecting layer 12. The surface emitting laser device 1 includes a removal portion 20 formed on the second semiconductor layer 9 (the first main surface 3). The removal portion 20 may be referred to as a “trench.” The removal portion 20 is formed by digging down the second semiconductor layer 9 (the first main surface 3) toward the first semiconductor layer 6. The removal portion 20 penetrates the second contact layer 13, the second light reflecting layer 12, the light generating layer 11, and the first light reflecting layer 10 to reach the first contact layer 8. The removal portion 20 is formed inwardly at a distance from the peripheral edge (the first to fourth side surfaces 5A to 5D) of the second semiconductor layer 9 in a plan view, and is formed in an annular shape surrounding the inner portion of the second semiconductor layer 9.

The removal portion 20 includes an inner wall 21, an outer wall 22, and a bottom wall 23 connecting the inner wall 21 and the outer wall 22. In this embodiment, the inner wall 21 is formed in a circular shape in a plan view. The inner wall 21 may be formed in a polygonal shape, an elliptical shape, or the like in a plan view. The inner wall 21 exposes the first light reflecting layer 10, the light generating layer 11, the second light reflecting layer 12, and the second contact layer 13.

In this embodiment, the outer wall 22 is formed in a square shape along the peripheral edge (the first to fourth side surfaces 5A to 5D) of the second semiconductor layer 9 in a plan view. The planar shape of the outer wall 22 is arbitrary and does not necessarily have to match the planar shape of the peripheral edge of the second semiconductor layer 9. The outer wall 22 may be formed in a circular shape along the inner wall 21. The outer wall 22 may be formed in a polygonal shape, an elliptical shape, or the like in a plan view. The outer wall 22 exposes the first light reflecting layer 10, the light generating layer 11, the second light reflecting layer 12, and the second contact layer 13. The bottom wall 23 extends substantially parallel to the first main surface 3 to expose the first contact layer 8. The bottom wall 23 may expose the semiconductor substrate 7.

The surface emitting laser device 1 includes at least one laser diode structure 30 (one laser diode structure 30 in this embodiment) partitioned in a plateau shape (mesa shape) in the second semiconductor layer 9 by the removal portion 20. The laser diode structure 30 includes the first light reflecting layer 10, the light generating layer 11, the second light reflecting layer 12, and the second contact layer 13. The laser diode structure 30 includes a cathode (first polarity) including the first light reflecting layer 10 (the first contact layer 8) and an anode (second polarity) including the second light reflecting layer 12 (the second contact layer 13).

The laser diode structure 30 generates a laser beam by resonance-reflecting light, which is generated by the light generating layer 11, by the first light reflecting layer 10 and the second light reflecting layer 12, and emits the laser beam toward the first semiconductor layer 6 side. In this embodiment, the laser diode structure 30 generates the laser beam in an infrared region. The laser beam may have a peak wavelength in a range of 850 nm or more and 1,100 nm or less. The peak wavelength of the laser beam may be in a range of 900 nm or more and 980 nm or less.

In this embodiment, the laser diode structure 30 is partitioned in a cone frustum shape (truncated cone shape) in the second semiconductor layer 9 (that is, on the first semiconductor layer 6). The shape of the laser diode structure 30 is arbitrary. The laser diode structure 30 may be partitioned in a polygonal frustum shape, an elliptical frustum shape, or the like according to the shape of the removal portion 20. The laser diode structure 30 does not necessarily have to be partitioned in a frustum shape, and may be partitioned in a columnar shape protruding substantially vertically along the normal direction Z.

In this embodiment, the laser diode structure 30 is formed to be deviated from a center of the second semiconductor layer 9 (that is, a center of the first main surface 3) in a plan view. Specifically, when a straight line SL1 (see a two-dot chain line portion) passing through the center of the second semiconductor layer 9 in the first direction X in a plan view is set, the laser diode structure 30 is formed so as to be deviated from the straight line SL1 toward the second side surface 5B with respect to the second direction Y. That is, the laser diode structure 30 is formed so that a distance from the second side surface 5B with respect to the second direction Y is less than a distance from the first side surface 5A. The laser diode structure 30 may overlap with the straight line SL1 or may be formed at a distance from the straight line SL1 in the second direction Y.

The laser diode structure 30 includes a first base portion 31, a first top surface 32, and a first side wall 33 connecting the first base portion 31 and the first top surface 32. The first base portion 31 is composed of a point where the laser diode structure 30 starts to protrude, and is formed by the first semiconductor layer 6 (the first contact layer 8 in this embodiment). The first base portion 31 is formed in a circular shape in a plan view. A diameter (maximum value) of the first base portion 31 in a plan view may be 30 μm or more and 2,000 μm or less. The diameter of the first base portion 31 is also a diameter (maximum value) of the laser diode structure 30.

The first top surface 32 is composed of a portion of the first main surface 3 and is formed by the second semiconductor layer 9 (the second contact layer 13). In this embodiment, the first top surface 32 has a flat area smaller than the flat area of the first base portion 31 in a plan view, and is surrounded by the first base portion 31. A width (maximum value) of the first top surface 32 may be 29 μm or more and 2,999 μm or less. The first side wall 33 is formed by the inner wall 21 of the removal portion 20. In this embodiment, the first side wall 33 is inclined downward from the first top surface 32 toward the first base portion 31. A first inclination angle θ1 formed between the first side wall 33 and the first top surface 32 may be 90 degrees or more and 120 degrees or less. The first inclination angle θ1 is an angle formed between a straight line, which connects the peripheral edge of the first base portion 31 and the peripheral edge of the first top surface 32, and the first top surface 32 in the laser diode structure 30 in a cross-sectional view.

The surface emitting laser device 1 includes a first insulating layer 34 formed inside the laser diode structure 30. The first insulating layer 34 partially shields a current path inside the laser diode structure 30. The first insulating layer 34 may be referred to as a “current shielding layer.” The first insulating layer 34 may be regarded as an element of the laser diode structure 30. The first insulating layer 34 is interposed in an arbitrary region between the first light reflecting layer 10 and the first top surface 32.

The first insulating layer 34 may be interposed in a region between the first light reflecting layer 10 and the light generating layer 11, or may be interposed in an arbitrary region between the light generating layer 11 and the first top surface 32. Of course, one first insulating layer 34 may be interposed in a region between the first light reflecting layer 10 and the light generating layer 11, and another first insulating layer 34 may be interposed in an arbitrary region between the first top surface 32 and the light generating layer 11. In this embodiment, the first insulating layer 34 is interposed in a region between the light generating layer 11 and the second light reflecting layer 12.

The first insulating layer 34 includes at least one of an insulator, a gap, and a damage layer. The insulator is formed by oxidizing a portion of the laser diode structure 30 inward from the peripheral edge of the laser diode structure 30. That is, the insulator is made of a portion of oxide of the laser diode structure 30. The gap is formed by removing a portion of the laser diode structure 30 inward from the peripheral edge of the laser diode structure 30.

The damage layer is formed by irradiating the peripheral edge of the laser diode structure 30 with protons. The first insulating layer 34 may include the gap and the insulator attached to the wall surface of the gap. This gap is formed by removing a portion of the insulator in a process of forming the insulator. In this embodiment, the first insulating layer 34 is made of oxide (Al oxide) of a p-type AlGaAs layer having an Al composition exceeding the Al composition of the second light reflecting layer 12 (the third AlGaAs layer).

The first insulating layer 34 includes a first opening 35 having a first diameter D1 in a plan view. The first diameter D1 is an opening width of the widest portion in the first opening 35. The first diameter D1 (maximum value) is less than the width of the first top surface 32. The first diameter D1 may be 28 μm or more and 1,998 μm or less. In this embodiment, the first opening 35 is formed in a circular shape in a plan view. The first opening 35 may be formed in a polygonal shape, an elliptical shape, or the like according to the planar shape of the laser diode structure 30.

The surface emitting laser device 1 includes a current constriction layer 36 partitioned by the first opening 35 inside the laser diode structure 30. The current constriction layer 36 may be regarded as an element of the laser diode structure 30. The current constriction layer 36 constricts a current flowing between the first base portion 31 and the first top surface 32. In this embodiment, the current constriction layer 36 is composed of a p-type AlGaAs layer having an Al composition exceeding the Al composition of the second light reflecting layer 12 (the third AlGaAs layer).

The current constriction layer 36 constricts a current flowing inside the laser diode structure 30 to increase the current density supplied to the light generating layer 11. The current density supplied to the light generating layer 11 is inversely proportional to the size of the current constriction layer 36. That is, the current density increases as the size (diameter) of the current constriction layer 36 decreases, and decreases as the size (diameter) of the current constriction layer 36 increases. The surface emitting laser device 1 further includes a frame structure 40 in the second semiconductor layer 9, which is partitioned in a plateau shape in a region different from the laser diode structure 30 by the removal portion 20. In this embodiment, the frame structure 40 is partitioned in an annular shape surrounding the laser diode structure 30 in a plan view. The frame structure 40 is partitioned in a square annular shape extending along the peripheral edge of the second semiconductor layer 9 in a plan view. The frame structure 40 includes the first light reflecting layer 10, the light generating layer 11, the second light reflecting layer 12, and the second contact layer 13. The frame structure 40 is formed in an electrically-floating state by the removal portion 20 and is electrically insulated from the laser diode structure 30. Therefore, the frame structure 40 does not generate light.

The frame structure 40 includes a second base portion 41, a second top surface 42, and a second side wall 43 connecting the second base portion 41 and the second top surface 42. The second base portion 41 is composed of a point where the frame structure 40 starts to protrude, and is formed by the first semiconductor layer 6 (the first contact layer 8 in this embodiment). The second base portion 41 is formed in a square shape in a plan view. The second top surface 42 is composed of a portion of the first main surface 3 and is formed by the second semiconductor layer 9 (the second contact layer 13). That is, the second top surface 42 of the frame structure 40 is located on the same plane as the first top surface 32 of the laser diode structure 30. The second top surface 42 is formed in a square annular shape extending along the peripheral edge (the first to fourth side surfaces 5A to 5D) of the second semiconductor layer 9 in a plan view.

The second side wall 43 is formed by the outer wall 22 of the removal portion 20. In this embodiment, the second side wall 43 is inclined downward from the second top surface 42 toward the second base portion 41. A second inclination angle θ2 formed between the second side wall 43 and the second top surface 42 may be 90 degrees or more and 120 degrees or less. The second inclination angle θ2 is an angle formed between a straight line, which connects the peripheral edge of the second base portion 41 and the peripheral edge of the second top surface 42, and the second top surface 42 in the frame structure 40 in a cross-sectional view. The frame structure 40 relieves a stress applied to the laser diode structure 30 when the surface emitting laser device 1 is mounted on the connection target.

The surface emitting laser device 1 includes a first insulating layer 34 and a current constriction layer 36, which are formed inside the frame structure 40. The first insulating layer 34 and the current constriction layer 36 on the frame structure 40 side have substantially the same structure as the first insulation layer 34 and the current constriction layer 36 on the laser diode structure 30 side. The description of the first insulating layer 34 and the current constriction layer 36 on the laser diode structure 30 side is applied to the first insulating layer 34 and the current constriction layer 36 on the frame structure 40 side except that the current-constricting effect is not generated.

The surface emitting laser device 1 includes a main surface insulating layer 50 that covers the second semiconductor layer 9. The main surface insulating layer 50 includes at least one of a silicon oxide film and a silicon nitride film. The main surface insulating layer 50 may include a laminated structure including at least one of a silicon oxide film and a silicon nitride film. The main surface insulating layer 50 may include a single-layer structure including a silicon oxide film or a silicon nitride film. In this embodiment, the main surface insulating layer 50 includes a single-layer structure composed of a silicon nitride film.

The main surface insulating layer 50 includes a second insulating layer 51 that covers the laser diode structure 30. The second insulating layer 51 covers the first top surface 32 and the first side wall 33 of the laser diode structure 30. The second insulating layer 51 includes a second opening 52 that selectively exposes the first top surface 32. The second opening 52 is formed in a region surrounded by the first opening 35 at a distance inward from the inner end portion (inner wall portion) of the first opening 35 in a plan view.

The second opening 52 has a second diameter D2 less than the first diameter D1 of the first opening 35 (D2<D1). The second diameter D2 is an opening width of the widest portion in the second opening 52. The second diameter D2 (maximum value) may be 27 μm or more and 1,997 μm or less. In this embodiment, the second opening 52 is formed in a circular shape in a plan view. The second opening 52 may be formed in a polygonal shape, an elliptical shape, or the like according to the planar shape of the laser diode structure 30.

Referring to FIG. 3, when an oblique line L0 connecting an opening end of the first opening 35 and an opening end of the second opening 52 is set in a cross-sectional view, a third inclination angle θ3 (acute angle) formed by the oblique line L0 with respect to the normal direction Z of the first top surface 32 may exceed 0 degree and be equal to or less than 45 degrees. The third inclination angle θ3 may be not less than 10 degrees. Particularly, the third inclination angle θ3 may not exceed 30 degrees (10 degrees≤θ3≤30 degrees).

A fourth inclination angle θ4 (obtuse angle) formed by the oblique line L0 with respect to the tangential direction of the first top surface 32 may exceed 90 degrees and be equal to or less than 135 degrees. The tangential direction includes the first direction X and the second direction Y. The fourth inclination angle θ4 may be not less than 100 degrees. Particularly, the fourth inclination angle θ4 may not exceed 120 degrees (100 degrees≤θ4≤120 degrees). The fourth inclination angle θ4 may exceed the first inclination angle θ1 of the laser diode structure 30.

In a cross-sectional view, when a first straight line L1 passing through the opening end of the first opening 35 in the normal direction Z of the first top surface 32 and a second straight line L2 passing through the opening end of the second opening 52 in the normal direction Z of the first top surface 32 are set, a distance D between the first straight line L1 and the second straight line L2 with respect to the tangential direction of the first top surface 32 may exceed 0 μm and be equal to or less than 200 μm. The distance D may be 10 μm or more and 50 μm or less.

The main surface insulating layer 50 includes a third insulating layer 53 that covers a region outside the laser diode structure 30 in the second semiconductor layer 9. The third insulating layer 53 is connected to the second insulating layer 51 at the first base portion 31 of the laser diode structure 30 and covers the removal portion 20 and the frame structure 40. Specifically, the third insulating layer 53 covers the bottom wall 23 of the removal portion 20, and the second top surface 42 and the second side wall 43 (the outer wall 22 of the removal portion 20) of the frame structure 40. The third insulating layer 53 may cover the entire area of the bottom wall 23 of the removal portion 20 and the entire area of the second side wall 43 (the outer wall 22 of the removal portion 20) of the frame structure 40.

The third insulating layer 53 includes a third opening 54 that exposes the first contact layer 8 in a portion covering the bottom wall 23 of the removal portion 20. The third opening 54 is formed at a distance from the laser diode structure 30 in a plan view. The third opening 54 is formed in a band shape extending along the laser diode structure 30. Specifically, the third opening 54 is formed in a curved band shape (C shape) extending along the laser diode structure 30 in a plan view.

The third insulating layer 53 is formed at a portion covering the second top surface 42 of the frame structure 40 at a distance inward from the peripheral edge (the first to fourth side surfaces 5A to 5D) of the second semiconductor layer 9. The third insulating layer 53 partitions a dicing street 55 that exposes the second semiconductor layer 9 between the third insulating layer 53 and the peripheral edge of the second semiconductor layer 9. The dicing street 55 is formed in an annular shape (square annular shape in this embodiment) surrounding the removal portion 20 in a plan view.

The surface emitting laser device 1 includes a first electrode film 61 and a second electrode film 62, which are formed on the main surface insulating layer 50. The first electrode film 61 is electrically connected to the cathode of the laser diode structure 30, and the second electrode film 62 is electrically connected to the anode of the laser diode structure 30. The first electrode film 61 includes a first pad electrode film 61a, a first wiring electrode film 61b, and a first connection electrode film 61c. The first pad electrode film 61a is arranged on the second top surface 42 of the frame structure 40 in a plan view. In this embodiment, the first pad electrode film 61a is arranged on the end portion of one side (the first side surface 5A side) of the second top surface 42 in a plan view. The first pad electrode film 61a is formed in a band shape (rectangular shape) extending in the first direction X. The first pad electrode film 61a may have a length exceeding the width (the diameter of the first base portion 31) of the laser diode structure 30 with respect to the first direction X.

The first wiring electrode film 61b is drawn out from the first pad electrode film 61a in a band shape in the removal portion 20. The first wiring electrode film 61b extends in a straight line shape in a region between the first pad electrode film 61a and the laser diode structure 30. In this embodiment, the first wiring electrode film 61b is formed in a straight line band shape extending in the second direction Y from the first pad electrode film 61a toward the laser diode structure 30. The first wiring electrode film 61b is drawn out up to the third opening 54. The first wiring electrode film 61b has a first wiring width W1. The first wiring width W1 is the width of the first wiring electrode film 61b in a direction (the first direction X) orthogonal to a direction (the second direction Y) in which the first wiring electrode film 61b extends.

The first connection electrode film 61c is drawn out from the first wiring electrode film 61b into the third opening 54 so as to enter the third opening 54 from above the main surface insulating layer 50 (the third insulating layer 53). The first connection electrode film 61c is electrically connected to the first contact layer 8 in the third opening 54. The first connection electrode film 61c is formed at a distance from the laser diode structure 30 and covers the entire area of the third opening 54.

In this embodiment, the first connection electrode film 61c is formed in a curved band shape (C shape) extending along the third opening 54 (the laser diode structure 30) in a plan view. The first connection electrode film 61c includes a pair of end portions in a region outside the third opening 54 in a plan view, and partitions an open portion 61d that exposes the main surface insulating layer 50 (the third insulating layer 53). In this embodiment, the open portion 61d is formed at a position facing the first wiring electrode film 61b (the first pad electrode film 61a) with the laser diode structure 30 interposed therebetween in a plan view.

The second electrode film 62 is formed on the main surface insulating layer 50 at a distance from the first electrode film 61. The second electrode film 62 includes a second pad electrode film 62a, a second wiring electrode film 62b, and a second connection electrode film 62c. The second pad electrode film 62a is arranged on the second top surface 42 of the frame structure 40 in a plan view. In this embodiment, the second pad electrode film 62a is arranged on an end portion of the other end side (the second side surface 5B side) of the second top surface 42 at a distance from the first pad electrode film 61a in a plan view. The second pad electrode film 62a faces the first pad electrode film 61a with the laser diode structure 30 interposed therebetween in a plan view.

The second pad electrode film 62a is located on the same straight line as the laser diode structure 30 and the first pad electrode film 61a. The second pad electrode film 62a is formed in a band shape (rectangular shape) extending in the first direction X. The second pad electrode film 62a may have a length exceeding the width (the diameter of the first base portion 31) of the laser diode structure 30 with respect to the first direction X. The length of the second pad electrode film 62a may be substantially equal to the length of the first pad electrode film 61a.

The second wiring electrode film 62b is drawn out from the second pad electrode film 62a in a band shape in the removal portion 20. The second wiring electrode film 62b has a width smaller than the width of the open portion 61d of the first connection electrode film 61c, and is drawn out up to the first top surface 32 of the laser diode structure 30 by passing through the open portion 61d. The second wiring electrode film 62b extends in a straight line shape in a region between the second pad electrode film 62a and the first top surface 32 of the laser diode structure 30.

In this embodiment, the second wiring electrode film 62b is formed in a straight line band shape extending in the second direction Y from the second pad electrode film 62a toward the laser diode structure 30. In this embodiment, the second wiring electrode film 62b is formed on the same straight line as the first wiring electrode film 61b in a plan view, and faces the first wiring electrode film 61b with the laser diode structure 30 interposed therebetween. The second wiring electrode film 62b may have a second wiring width W2 that is less than the first wiring width W1 of the first wiring electrode film 61b (W2<W1). The second wiring width W2 is a width in a direction (the first direction X) orthogonal to a direction (the second direction Y) in which the second wiring electrode film 62b extends.

The second connection electrode film 62c is drawn out from the second wiring electrode film 62b onto the first top surface 32 of the laser diode structure 30, and enters the second opening 52 from above the main surface insulating layer 50 (the second insulating layer 51). The second connection electrode film 62c is electrically connected to the second contact layer 13 in the second opening 52. The second connection electrode film 62c is electrically connected to the first top surface 32 in the region surrounded by the first opening 35 in a plan view. That is, in a plan view, the connection area of the second connection electrode film 62c with respect to the first top surface 32 is smaller than the opening area of the first opening 35. The second connection electrode film 62c may be formed in a circular shape in a plan view.

In this embodiment, the first electrode film 61 and the second electrode film 62 each include a laminated structure including a barrier metal film 63 and a main electrode film 64, which are laminated in this order from the main surface insulating layer 50 side. The barrier metal film 63 may be formed of a Ti-based metal film. The barrier metal film 63 may include a single-layer structure or a laminated structure including at least one of a Ti film and a TiN film. The main electrode film 64 may be composed of an Au-based metal film. The main electrode film 64 may include at least one of a pure Au film (Au film having a purity of 99% or more) and an Au alloy film.

The surface emitting laser device 1 includes a first terminal electrode 65, a second terminal electrode 66, and a third terminal electrode 67. The first to third terminal electrodes 65 to 67 are electrodes that are externally connected to the connection target. The first terminal electrode 65 is arranged on the first electrode film 61. Specifically, the first terminal electrode 65 is arranged on the first pad electrode film 61a. The first terminal electrode 65 may be formed in a band shape (rectangular shape) extending along the first pad electrode film 61a in a plan view.

The second terminal electrode 66 is arranged on the second electrode film 62. Specifically, the second terminal electrode 66 is arranged on the second pad electrode film 62a. The second terminal electrode 66 may be formed in a band shape (rectangular shape) extending along the second pad electrode film 62a in a plan view. The second terminal electrode 66 faces the first terminal electrode 65 with the laser diode structure 30 interposed therebetween in a plan view. That is, the second terminal electrode 66 is located on the same straight line as the laser diode structure 30 and the first terminal electrode 65.

The third terminal electrode 67 is arranged on the second electrode film 62 at a position different from that of the second terminal electrode 66. Specifically, the third terminal electrode 67 is arranged on the second connection electrode film 62c. The third terminal electrode 67 may be formed in a circular shape in a plan view. The third terminal electrode 67 may cover the entire area of the second opening 52. The third terminal electrode 67 is located on the same straight line as the laser diode structure 30, the first terminal electrode 65, and the second terminal electrode 66 in a plan view. The third terminal electrode 67 is arranged at a position close to the second terminal electrode 66 with respect to the first terminal electrode 65 in a plan view. That is, the third terminal electrode 67 is arranged so that a distance between the third terminal electrode 67 and the second terminal electrode 66 is less than a distance between the third terminal electrode 67 and the first terminal electrode 65.

The first to third terminal electrodes 65 to 67 have a thickness exceeding the thickness of the first and second electrode films 61 and 62. The first to third terminal electrodes 65 to 67 may have the same thickness in this embodiment. The first to third terminal electrodes 65 to 67 may be formed of an Au-based metal film. The first to third terminal electrodes 65 to 67 may include at least one of a pure Au film (Au film having a purity of 99% or more) and an Au alloy film. The first to third terminal electrodes 65 to 67 may have a thickness of 1 μm or more and 10 μm or less.

As described above, the surface emitting laser device 1 includes the first semiconductor layer 6, the second semiconductor layer 9, the laser diode structure 30, the first insulating layer 34, and the second insulating layer 51. The first semiconductor layer 6 is of an n-type (first conductive type) conductive type. The second semiconductor layer 9 includes the n-type first light reflecting layer 10, the light generating layer 11, and the p-type (second conductive type) second light reflecting layer 12, which are laminated in this order from the first semiconductor layer 6 side. The laser diode structure 30 is partitioned in a plateau shape including the first top surface 32 by the removal portion 20 which is formed by digging down the second semiconductor layer 9, and emits a laser beam to the first semiconductor layer 6 side.

The first insulating layer 34 is formed inside the laser diode structure 30 and includes the first opening 35 having the first diameter D1 in a plan view. The first opening 35 partitions the current constriction layer 36 inside the laser diode structure 30. The second insulating layer 51 covers the first top surface 32 and includes the second opening 52 having the second diameter D2 less than the first diameter D1 in the region surrounded by the first opening 35 in a plan view.

According to this structure, it is possible to provide a surface emitting laser device 1 including a novel structure. That is, according to the surface emitting laser device 1, it is possible to suppress the spread of a current generated in a region between the first opening 35 and the second opening 52 inside the laser diode structure 30. This makes it possible to suppress variations (deviations) in light emitting points in the light generating layer 11. As a result, it is possible to improve the directivity of the laser beam in the structure in which the laser beam is emitted to the first semiconductor layer 6 side.

When the oblique line L0 connecting the opening end of the first opening 35 and the opening end of the second opening 52 is set in a cross-sectional view, the third inclination angle θ3 formed by the oblique line L0 with respect to the normal direction Z of the first top surface 32 may exceed 0 degree and be equal to or less than 45 degrees. According to this structure, it is possible to appropriately suppress the spread of a current inside the laser diode structure 30. In a cross-sectional view, when the first straight line L1 passing through the opening end of the first opening 35 in the normal direction Z of the first top surface 32 and the second straight line L2 passing through the opening end of the second opening 52 in the normal direction Z of the first top surface 32 are set, the distance D between the first straight line L1 and the second straight line L2 with respect to the tangential direction of the first top surface 32 may exceed 0 μm and be equal to or less than 200 μm. According to this structure, it is possible to appropriately suppress the spread of the current inside the laser diode structure 30.

The first light reflecting layer 10 may have the first thickness T1 and the second light reflecting layer 12 may have the second thickness T2 (T1<T2) exceeding the first thickness T1. According to this structure, it is possible to appropriately emit the laser beam to the first semiconductor layer 6 side. The laser diode structure 30 may be partitioned in the form of a frustum-shaped plateau. According to this structure, it is possible to appropriately suppress the spread of a current in the laser diode structure 30 with a structure in which the current is likely to spread in the width direction (the diameter direction).

The first insulating layer 34 may be interposed between the first top surface 32 and the light generating layer 11 inside the laser diode structure 30. According to this structure, it is possible to suppress the spread of a current in the region between the first top surface 32 and the light generating layer 11. The second semiconductor layer 9 may include the mounting surface facing the connection target. According to this structure, it is possible to provide a flip-chip type surface emitting laser device 1.

The surface emitting laser device 1 may include the frame structure 40 partitioned in a plateau shape in a region different from the laser diode structure 30 by the removal portion 20 in the second semiconductor layer 9. According to this structure, in an example in which the surface emitting laser device 1 is connected by flip-chip, it is possible to relieve a stress, which is applied to the laser diode structure 30, in the frame structure 40. The frame structure 40 may be formed in an electrically-floating state. According to this structure, it is possible to suppress fluctuations in the electrical characteristics (including optical characteristics such as luminance) of the laser diode structure 30 due to the frame structure 40.

The surface emitting laser device 1 may include the third insulating layer 53, the first electrode film 61, and the second electrode film 62. The third insulating layer 53 may include the third opening 54 that covers a region outside the laser diode structure 30 in the second semiconductor layer 9 and exposes the first semiconductor layer 6. The first electrode film 61 may be electrically connected to the first semiconductor layer 6 in the third opening 54. The second electrode film 62 may be electrically connected to the first top surface 32 in the second opening 52.

The third insulating layer 53 may cover the second semiconductor layer 9 so as to expose the peripheral edge portion of the second semiconductor layer 9. The first electrode film 61 may include the first pad electrode film 61a arranged on the third insulating layer 53 at a distance from the laser diode structure 30, the first wiring electrode film 61b drawn out from the first pad electrode film 61a, and the first connection electrode film 61c electrically connected to the first semiconductor layer 6 in the third opening 54. The second electrode film 62 may include the second pad electrode film 62a arranged on the third insulating layer 53 at a distance from the laser diode structure 30, the second wiring electrode film 62b drawn out from the second pad electrode film 62a, and the second connection electrode film 62c electrically connected to the laser diode structure 30 in the second opening 52.

The third opening 54 may extend in a curved band shape along the laser diode structure 30 in a plan view, and the first connection electrode film 61c may extend in a curved band shape along the laser diode structure 30 in a plan view. According to this structure, it is possible to supply a current from the first electrode film 61 to the laser diode structure 30 along the circumferential direction of the laser diode structure 30. The first pad electrode film 61a may face the second pad electrode film 62a with the laser diode structure 30 interposed therebetween in a plan view. The first wiring electrode film 61b may be drawn out in a straight line shape toward the laser diode structure 30, and the second wiring electrode film 62b may be drawn out in a straight line shape toward the laser diode structure 30. According to this structure, it is possible to reduce the wiring resistance of the first electrode film 61 and the wiring resistance of the second electrode film 62. The second wiring electrode film 62b may be located on the same straight line as the first wiring electrode film 61b in a plan view.

The first wiring electrode film 61b may have the first wiring width W1, and the second wiring electrode film 62b may have the second wiring width W2 less than the first wiring width W1 (W2<W1). According to this structure, in an example in which the first connection electrode film 61c extends in a curved band shape along the laser diode structure 30 in a plan view, it is possible to increase the wiring length of the first connection electrode film 61c. As a result, it is possible to increase a current supplied from the first connection electrode film 61c to the laser diode structure 30.

The laser diode structure 30 may be partitioned at a position deviated from the center of the second semiconductor layer 9 in a plan view. The surface emitting laser device 1 may include the laser diode structure 30 which is a single laser diode structure 30. The first semiconductor layer 6 may include a laminated structure including the n-type semiconductor substrate 7 and the n-type first contact layer 8 having an impurity concentration substantially equal to or higher than that of the semiconductor substrate 7. In this case, the second semiconductor layer 9 may be formed on the first contact layer 8.

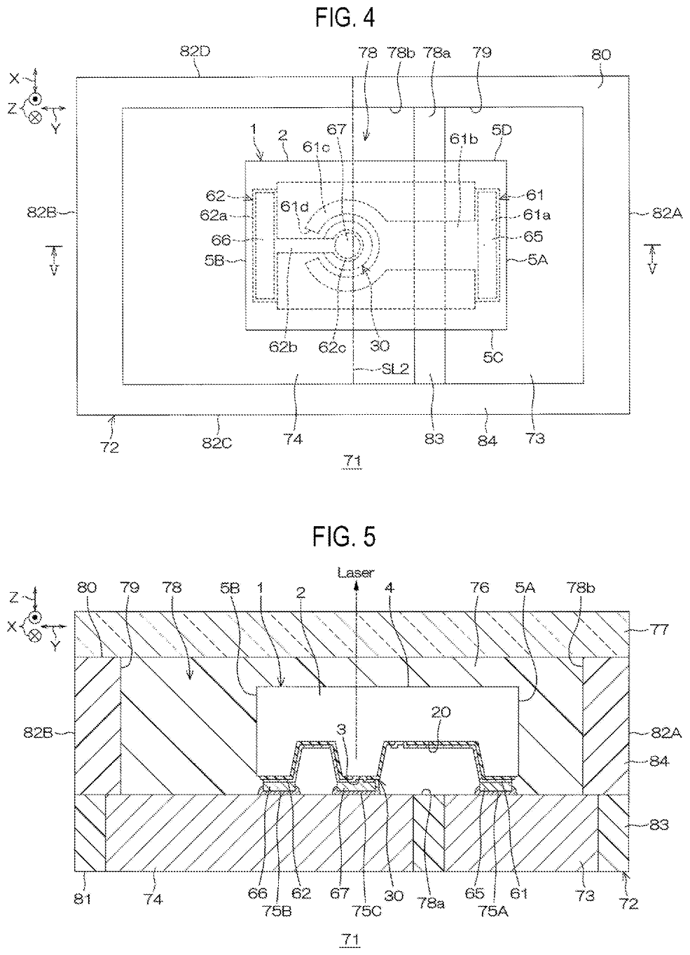

FIG. 4 is a plan view showing a package 71 on which the surface emitting laser device 1 shown in FIG. 1 is mounted. FIG. 5 is a cross-sectional view taken along line V-V shown in FIG. 4. Hereinafter, the same structures as those in FIGS. 1 to 3 are denoted by the same reference numerals, and explanation thereof will be omitted. Referring to FIGS. 4 and 5, the package 71 includes a housing 72, a first electrode 73, a second electrode 74, a surface emitting laser device 1, a plurality of conductive bonding materials 75A to 75C, a sealant 76, and a window member 77. The window member 77 may be referred to as a “light extraction window.” The housing 72 has an internal space 78 and an opening 79 communicating with the internal space 78. The first electrode 73 is exposed inside and outside the housing 72. The second electrode 74 is exposed inside and outside the housing 72 at a position different from that of the first electrode 73.

The surface emitting laser device 1 is accommodated in the internal space 78 in a flip-chip posture with the first semiconductor layer 6 facing the opening 79 side and the laser diode structure 30 facing the housing 72 side, and is electrically connected to the first electrode 73 and the second electrode 74. A laser beam generated by the surface emitting laser device 1 is extracted from the opening 79 side. The plurality of conductive bonding materials 75A to 75C connect the surface emitting laser device 1 to the first electrode 73 and the second electrode 74 in the internal space 78. The sealant 76 is formed of a translucent organic insulator or a transparent organic insulator, and seals the surface emitting laser device 1 in the internal space 78. The window member 77 is a lid member formed of a translucent insulator or a transparent insulator, and closes the opening 79. Hereinafter, a specific configuration of the package 71 will be described.

The housing 72 is formed in a hexahedral shape (rectangular parallelepiped shape in this embodiment). The housing 72 may be formed in a cubic shape. The housing 72 includes a first main surface 80 on one side, a second main surface 81 on the other side, and first to fourth side surfaces 82A to 82D connecting the first main surface 80 and the second main surface 81. The first main surface 80 and the second main surface 81 are formed in a square shape (rectangular shape in this embodiment) in a plan view as seen from their normal direction Z.

The first side surface 82A and the second side surface 82B extend along the first direction X and face the second direction Y. In this embodiment, the first side surface 82A and the second side surface 82B form the short side of the housing 72. The third side surface 82C and the fourth side surface 82D extend along the second direction Y and face the first direction X. In this embodiment, the third side surface 82C and the fourth side surface 82D form the long side of the housing 72.

The housing 72 has the internal space 78 dug down from the first main surface 80 up to a middle portion in the thickness direction. The internal space 78 has a bottom wall 78a and a side wall 78b. The bottom wall 78a extends parallel to the first main surface 80. The side wall 78b is formed in a square shape in a plan view and extends substantially perpendicular to the bottom wall 78a (the first main surface 80). The side wall 78b partitions the opening 79 on the first main surface 80 side.

Specifically, the housing 72 includes a base member 83 and a frame member 84. The base member 83 is a plate-like member formed of an insulator (specifically, an organic insulator). The base member 83 forms portions of the second main surface 81 and the first to fourth side surfaces 82A to 82D of the housing 72. Further, the base member 83 forms the bottom wall 78a of the internal space 78. The frame member 84 is an annular member formed of an insulator (specifically, an organic insulator). The frame member 84 is attached to the base member 83. The frame member 84 may be formed integrally with the base member 83. The frame member 84 forms portions of the first main surface 80 and the first to fourth side surfaces 82A to 82D of the housing 72. Further, the frame member 84 forms the side wall 78b of the internal space 78.

The first electrode 73 is formed of a metal (for example, Cu) columnar or plate-like member. In this embodiment, the first electrode 73 is formed in a square shape in a plan view.

The first electrode 73 is buried in the housing 72 so as to be exposed from the second main surface 81 and the internal space 78. Specifically, the first electrode 73 is buried in the base member 83 so as to be exposed from one main surface and the other main surface of the base member 83.

In this embodiment, the first electrode 73 is buried on one side (the first side surface 82A side) of the second direction Y. In this embodiment, the first electrode 73 has a first electrode width that is relatively narrow with respect to the second direction Y, and is arranged so as to be unevenly distributed on one side of the second direction Y. That is, when a straight line SL2 (see a two-dot chain line portion) that passes through the center of the first main surface 80 in the first direction X is set, the first electrode 73 is arranged to be biased to one side of the second direction Y with respect to the straight line SL2. The first electrode 73 may overlap the straight line SL2 or may be arranged at a distance from the straight line SL2.

The second electrode 74 is formed of a metal (for example, Cu) columnar or plate-like member. In this embodiment, the second electrode 74 is formed in a square shape in a plan view. The second electrode 74 is buried in the housing 72 at a distance from the first electrode 73 so as to be exposed from the second main surface 81 and the internal space 78. Specifically, the second electrode 74 is buried in the base member 83 so as to be exposed from one main surface and the other main surface of the base member 83.

In this embodiment, the second electrode 74 is buried on the other side (the second side surface 82B side) of the second direction Y. The second electrode 74 has a second electrode width that exceeds the first electrode width of the first electrode 73 with respect to the second direction Y. That is, a flat area of the second electrode 74 occupying the bottom wall 78a of the internal space 78 exceeds a flat area of the first electrode 73 occupying the bottom wall 78a of the internal space 78. The surface emitting laser device 1 is arranged on the first electrode 73 and the second electrode 74 in a posture in which the first main surface 3 faces the bottom wall 78a of the internal space 78, and is electrically connected to the first electrode 73 and the second electrode 74. The first terminal electrode 65 is electrically connected to the first electrode 73. The second terminal electrode 66 is electrically connected to the second electrode 74. The third terminal electrode 67 is electrically connected to the second electrode 74. The laser diode structure 30 faces the second electrode 74 in a plan view, and is arranged closer to the central portion of the housing 72 than the central portion of the chip 2 (the second semiconductor layer 9). Heat generated in the laser diode structure 30 is dissipated to the outside via the third terminal electrode 67 and the second electrode 74.

The plurality of conductive bonding materials 75A to 75C are each made of metal paste or solder. In this embodiment, the plurality of conductive bonding materials 75A to 75C are each made of silver paste. The thickness of each of the plurality of conductive bonding materials 75A to 75C may be 10 μm or more and 50 μm or less. The plurality of conductive bonding materials 75A to 75C include a first conductive bonding material 75A, a second conductive bonding material 75B, and a third conductive bonding material 75C.

The first conductive bonding material 75A is interposed between the first electrode 73 and the first terminal electrode 65, and electrically and mechanically connects the first electrode 73 and the first terminal electrode 65. The second conductive bonding material 75B is interposed between the second electrode 74 and the second terminal electrode 66, and electrically and mechanically connects the second electrode 74 and the second terminal electrode 66. The third conductive bonding material 75C is interposed between the second electrode 74 and the third terminal electrode 67, and electrically and mechanically connects the second electrode 74 and the third terminal electrode 67.

The sealant 76 is filled in the internal space 78 so as to cover the second main surface 4 and the first to fourth side surfaces 5A to 5D of the surface emitting laser device 1. The filling of the sealant 76 into a space partitioned between the bottom wall 78a of the internal space 78 and the removal portion 20 of the surface emitting laser device 1 is hindered by the frame structure 40 of the surface emitting laser device 1. The sealant 76 may expose the bottom wall 23 of the removal portion 20 of the surface emitting laser device 1.

Particularly, the sealant 76 may expose at least a portion or all of the laser diode structure 30. According to this structure, since a stress applied to the laser diode structure 30 from the sealant 76 can be relieved, it is possible to appropriately generate a laser beam in the laser diode structure 30. The sealant 76 does not necessarily have to be installed. Therefore, the package 71 without the sealant 76 may be adopted.

The window member 77 is attached to the first main surface 80 (the frame member 84) so as to close the opening 79. The window member 77 may be formed of an organic insulator or an inorganic insulator. The window member 77 may be a diffuser that diffuses the laser beam of the surface emitting laser device 1, or may be a transparent glass plate that transmits the laser beam of the surface emitting laser device 1. The window member 77 does not necessarily have to be installed. Therefore, the package 71 without the window member 77 may be adopted.

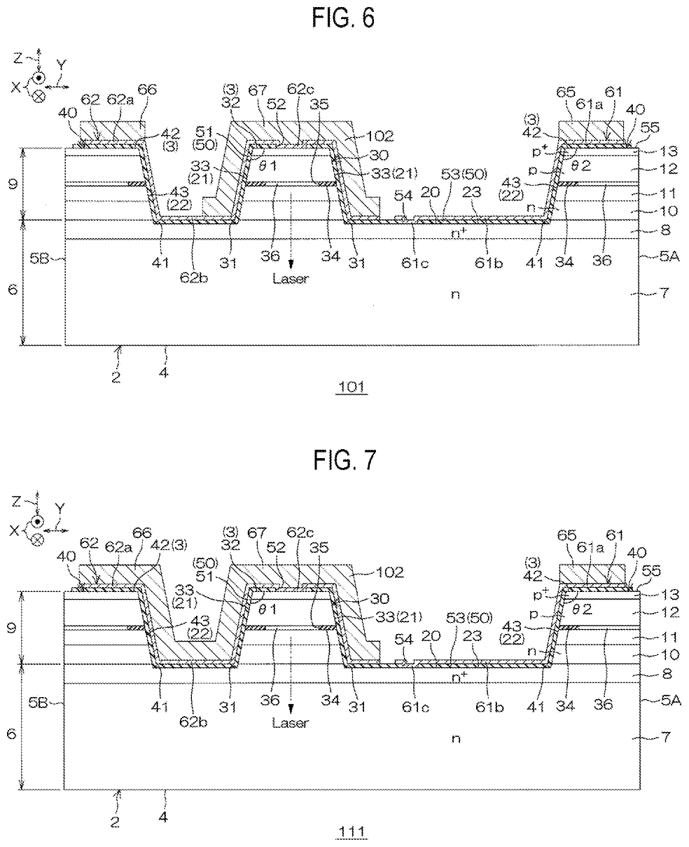

FIG. 6 corresponds to FIG. 2 and is a cross-sectional view showing a surface emitting laser device 101 according to a second embodiment of the present disclosure. Hereinafter, structures corresponding to the structures described for the surface emitting laser device 1 are denoted by the same reference numerals, and explanation thereof will be omitted. The second electrode film 62 according to the surface emitting laser device 101 includes the second wiring electrode film 62b that covers the first side wall 33 along the circumferential direction of the laser diode structure 30. The second wiring electrode film 62b may cover the entire area of the first side wall 33. The second wiring electrode film 62b covers the bottom wall 23 of the removal portion 20 at a distance from the first connection electrode film 61c. In this embodiment, the second wiring electrode film 62b includes a portion that covers the bottom wall 23 of the removal portion 20 over the entire area of the laser diode structure 30 in the circumferential direction.

The surface emitting laser device 101 includes a side wall electrode 102 that covers the second wiring electrode film 62b. The side wall electrode 102 covers the first side wall 33 along the circumferential direction of the laser diode structure 30. The side wall electrode 102 may cover the entire area of the first side wall 33. The side wall electrode 102 may cover the entire area of the first side wall 33 with the second wiring electrode film 62b and the main surface insulating layer 50 (the second insulating layer 51) interposed therebetween.

The side wall electrode 102 includes a portion that covers the bottom wall 23 of the removal portion 20 with the second wiring electrode film 62b interposed therebetween at a distance from the first connection electrode film 61c. In this embodiment, the second wiring electrode film 62b includes a portion that covers the bottom wall 23 of the removal portion 20 over the entire area of the laser diode structure 30 in the circumferential direction. The side wall electrode 102 is connected to the third terminal electrode 67 on the first top surface 32 of the laser diode structure 30.

The side wall electrode 102 has a thickness exceeding the thickness of each of the first and second electrode films 61 and 62. The side wall electrode 102 is made of the same material as the third terminal electrode 67, and has a thickness substantially equal to that of the third terminal electrode 67. The third terminal electrode 67 and the side wall electrode 102 may be formed by one electrode film. That is, the side wall electrode 102 can be regarded as a portion of the third terminal electrode 67 that covers the first side wall 33 of the laser diode structure 30.

As described above, the surface emitting laser device 101 includes the first semiconductor layer 6, the second semiconductor layer 9, the laser diode structure 30, the second wiring electrode film 62b (the electrode film), and the side wall electrode 102. The first semiconductor layer 6 is of an n-type (first conductive type) conductive type. The second semiconductor layer 9 includes the n-type first light reflecting layer 10, the light generating layer 11, and the p-type (second conductive type) second light reflecting layer 12, which are laminated in this order from the first semiconductor layer 6 side. The laser diode structure 30 is partitioned in a plateau shape including the first top surface 32 and the first side wall 33 by the removal portion 20 in which the second semiconductor layer 9 is dug down, and generates the laser beam.

The second wiring electrode film 62b covers the first side wall 33 of the laser diode structure 30. The side wall electrode 102 has a thickness exceeding the thickness of the second wiring electrode film 62b and covers the second wiring electrode film 62b. According to this structure, it is possible to absorb the heat, which is generated by the laser diode structure 30, by the side wall electrode 102. As a result, it is possible to suppress the temperature increase of the laser diode structure 30. Therefore, it is possible to appropriately generate light in the laser diode structure 30.

The second semiconductor layer 9 may have a mounting surface facing the connection target. In this case, the laser diode structure 30 may emit the laser beam to the first semiconductor layer 6 side. According to this structure, it is possible to provide a flip-chip type surface emitting laser device 101. Therefore, when the surface emitting laser device 101 is mounted on the above-described package 71, it is possible to efficiently transfer the heat, which is generated by the laser diode structure 30, to the second electrode 74 via the side wall electrode 102. As a result, it is possible to appropriately suppress the temperature increase of the laser diode structure 30 even when the laser diode structure 30 is mounted on the package 71.

The surface emitting laser device 101 may include the second connection electrode film 62c and the third terminal electrode 67. The second connection electrode film 62c covers the first top surface 32 and is electrically connected to the first top surface 32. The third terminal electrode 67 has a thickness exceeding the thickness of the second connection electrode film 62c and covers the second connection electrode film 62c. According to this structure, it is possible to absorb the heat, which is generated by the laser diode structure 30, by the third terminal electrode 67. That is, when the surface emitting laser device 101 is mounted on the above-described package 71, it is possible to efficiently transfer the heat, which is generated by the laser diode structure 30, to the second electrode 74 via the third terminal electrode 67 and the side wall electrode 102. In this structure, the side wall electrode 102 may be connected to the third terminal electrode 67 on the first top surface 32.

The second wiring electrode film 62b may cover the entire area of the first side wall 33, and the side wall electrode 102 may cover the entire area of the first side wall 33 with the second wiring electrode film 62b interposed therebetween. According to this structure, it is possible to efficiently absorb the heat, which is generated by the laser diode structure 30, by the side wall electrode 102. The side wall electrode 102 may contain Au-based metal. The Au-based metal has a relatively high thermal conductivity. Therefore, according to the side wall electrode 102 containing the Au-based metal, it is possible to efficiently absorb the heat generated by the laser diode structure 30.

FIG. 7 corresponds to FIG. 2 and is a cross-sectional view showing a surface emitting laser device 111 according to a third embodiment of the present disclosure. The surface emitting laser device 111 includes a shape in which the side wall electrode 102 of the surface emitting laser device 101 is modified. Hereinafter, structures corresponding to the structures described for the surface emitting laser device 101 are denoted by the same reference numerals, and explanation thereof will be omitted. Referring to FIG. 7, the side wall electrode 102 according to the surface emitting laser device 111 includes a portion that covers the entire area of the second wiring electrode film 62b and covers the bottom wall 23 and the outer wall 22 of the removal portion 20. The side wall electrode 102 is connected to the second terminal electrode 66 on the second top surface 42 of the frame structure 40. That is, the second terminal electrode 66, the third terminal electrode 67, and the side wall electrode 102 are formed by one electrode film.

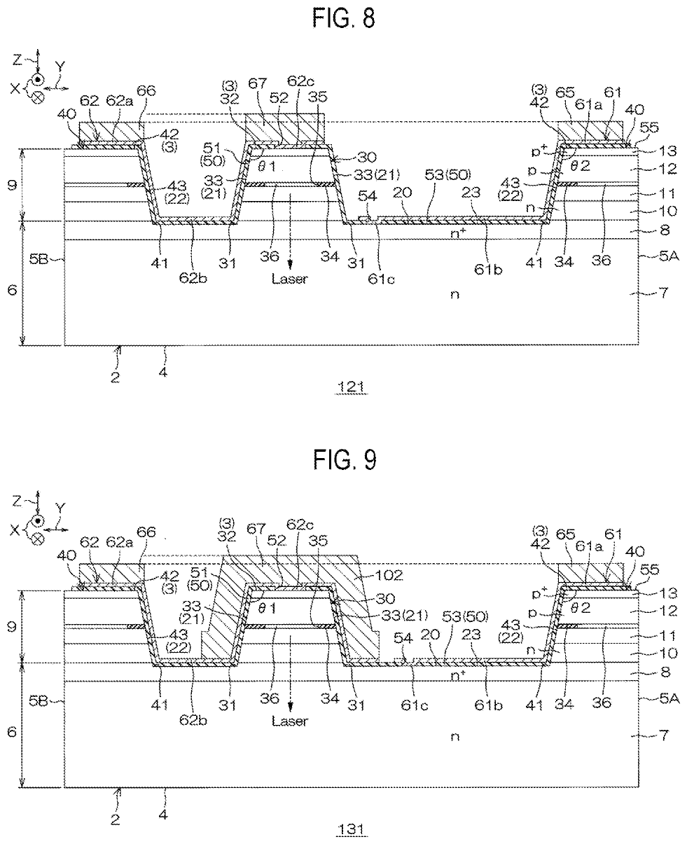

As described above, the surface emitting laser device 111 can also obtain the same effects as the effects described for the surface emitting laser device 101. FIG. 8 corresponds to FIG. 2 and is a cross-sectional view showing a surface emitting laser device 121 according to a fourth embodiment of the present disclosure. Hereinafter, structures corresponding to the structures described for the surface emitting laser device 1 are denoted by the same reference numerals, and explanation thereof will be omitted.

Similarly to the surface emitting laser device 1 according to the first embodiment, the surface emitting laser device 121 includes the first terminal electrode 65, the second terminal electrode 66, and the third terminal electrode 67. In this embodiment, the third terminal electrode 67 has a thickness exceeding the thickness of each of the first to second terminal electrodes 65 to 66. The first to second terminal electrodes 65 to 66 may each have a thickness of 1 μm or more and 10 μm or less. The third terminal electrode 67 may protrude from the electrode surfaces of the first to second terminal electrodes 65 to 66 in a range of 0.5 μm or more and 10 μm or less.

As described above, the surface emitting laser device 121 includes the first semiconductor layer 6, the second semiconductor layer 9, the laser diode structure 30, the frame structure 40, the first terminal electrode 65, the second terminal electrode 66, and the third terminal electrode 67. The first semiconductor layer 6 is of an n-type (first conductive type) conductive type. The second semiconductor layer 9 includes the n-type first light reflecting layer 10, the light generating layer 11, and the p-type (second conductive type) second light reflecting layer 12, which are laminated in this order from the first semiconductor layer 6 side. The laser diode structure 30 is partitioned in a plateau shape including the first top surface 32 and the first side wall 33 by the removal portion 20 in which the second semiconductor layer 9 is dug down, and generates the laser beam.

The frame structure 40 is partitioned in a plateau shape including the second top surface 42 and the second side wall 43 by the removal portion 20 in a region different from the laser diode structure 30 in the second semiconductor layer 9. The first terminal electrode 65 is arranged on the second top surface 42. The second terminal electrode 66 is arranged on the second top surface 42 at a distance from the first terminal electrode 65. The third terminal electrode 67 has a thickness exceeding the thickness of the first terminal electrode 65 and the thickness of the second terminal electrode 66, and is arranged on the first top surface 32. According to this structure, it is possible to absorb the heat, which is generated by the laser diode structure 30, by the relatively thick third terminal electrode 67. As a result, it is possible to suppress the temperature increase of the laser diode structure 30.

The second semiconductor layer 9 may have a mounting surface facing the connection target. In this case, the laser diode structure 30 may emit the laser beam to the first semiconductor layer 6 side. According to this structure, it is possible to provide a flip-chip type surface emitting laser device 121. When the surface emitting laser device 121 is mounted on the above-described package 71, the third terminal electrode 67 can be directly connected to the second electrode 74, or the third terminal electrode 67 can be brought closer to the second electrode 74 than the second terminal electrode 66. As a result, it is possible to shorten a heat transfer path (heat dissipation path) from the laser diode structure 30 to the second electrode 74. Therefore, it is possible to appropriately suppress the temperature increase of the laser diode structure 30 even when the surface emitting laser device 121 is mounted on the package 71.

The second terminal electrode 66 may have the same thickness as the first terminal electrode 65. The second terminal electrode 66 may face the first terminal electrode 65 with the laser diode structure 30 interposed therebetween in a plan view. The third terminal electrode 67 may be located on a straight line connecting the first terminal electrode 65 and the second terminal electrode 66 in a plan view. The third terminal electrode 67 may be arranged at a position closer to the second terminal electrode 66 than the first terminal electrode 65.

FIG. 9 corresponds to FIG. 2 and is a cross-sectional view showing a surface emitting laser device 131 according to a fifth embodiment of the present disclosure. The surface emitting laser device 131 includes a form in which the surface emitting laser device 101 according to the second embodiment is combined with the surface emitting laser device 121 according to the fourth embodiment. Hereinafter, structures corresponding to the structures described for the surface emitting laser device 101 and the surface emitting laser device 121 are denoted by the same reference numerals, and explanation thereof will be omitted.

Referring to FIG. 9, the surface emitting laser device 131 includes the side wall electrode 102 and the first to third terminal electrodes 65 to 67. The description of the side wall electrode 102 according to the second embodiment is applied to the side wall electrode 102. The description of the first to third terminal electrodes 65 to 67 according to the fourth embodiment is applied to the first to third terminal electrodes 65 to 67. As described above, the surface emitting laser device 131 can obtain the effects described for the surface emitting laser device 101 and the effects described for the surface emitting laser device 121. Of course, the surface emitting laser device 131 may have the side wall electrode 102 according to the third embodiment instead of the side wall electrode 102 according to the second embodiment.

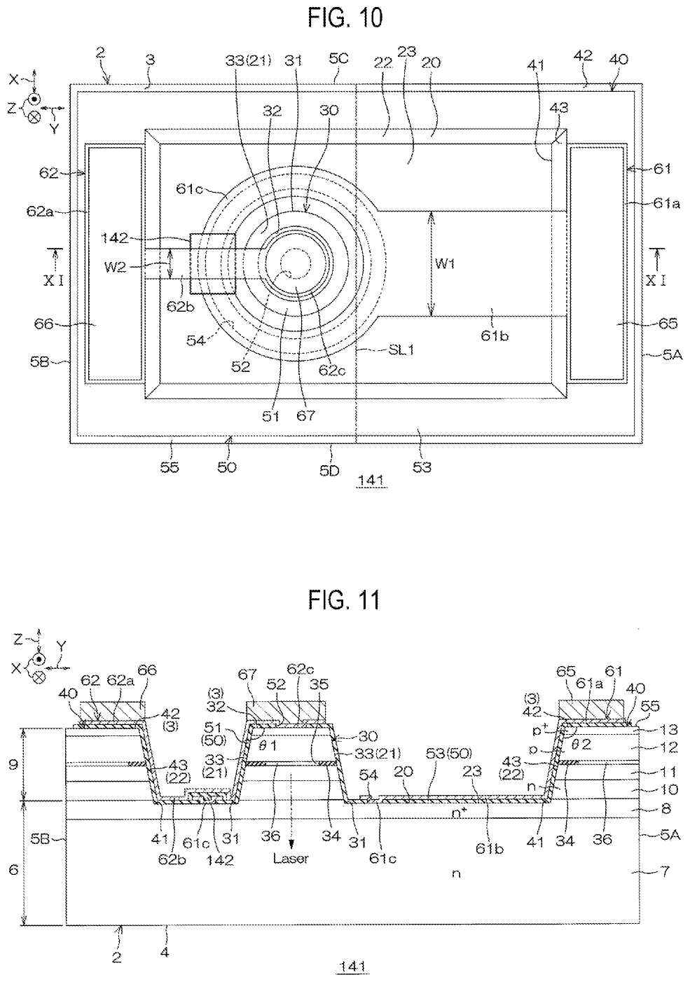

FIG. 10 is a plan view showing a surface emitting laser device 141 according to a sixth embodiment of the present disclosure. FIG. 11 is a cross-sectional view taken along line XI-XI shown in FIG. 10. Hereinafter, structures corresponding to the structures described for the surface emitting laser device 1 are denoted by the same reference numerals, and explanation thereof will be omitted. Referring to FIG. 10, in this embodiment, the third opening 54 according to the surface emitting laser device 141 is formed in an annular shape (a toric shape in this embodiment) surrounding the laser diode structure 30 in a plan view. In this embodiment, the first connection electrode film 61c is formed in an annular shape (a toric shape in this embodiment) surrounding the laser diode structure 30 in a plan view.

The surface emitting laser device 141 further includes a wiring insulating layer 142 that covers at least a portion of the first connection electrode film 61c. The wiring insulating layer 142 forms a drawing-out route for a wiring (the second connection electrode film 62c to be described later) on the first connection electrode film 61c. The wiring insulating layer 142 may cover the entire area of the first connection electrode film 61c, or may partially cover the first connection electrode film 61c so as to expose a portion of the first connection electrode film 61c.

The wiring insulating layer 142 may selectively cover the first wiring electrode film 61b and the first connection electrode film 61c so as to selectively expose the first pad electrode film 61a. In this case, the wiring insulating layer 142 may cover the entire area of an exposed surface of the main surface insulating layer 50 exposed from the first electrode film 61. In this case, the wiring insulating layer 142 may partition the dicing street 55 together with the main surface insulating layer 50.

In this embodiment, the second wiring electrode film 62b passes over the wiring insulating layer 142 from the second pad electrode film 62a and is drawn out in a band shape up to the first top surface 32 of the laser diode structure 30. That is, the second wiring electrode film 62b includes an intersection portion that intersects the first connection electrode film 61c with the wiring insulating layer 142 interposed therebetween. As described above, the surface emitting laser device 141 includes the first semiconductor layer 6, the second semiconductor layer 9, the laser diode structure 30, the main surface insulating layer 50, the third opening 54 (first contact opening), the second opening 52 (second contact opening), the first electrode film 61, the wiring insulating layer 142, and the second electrode film 62. The first semiconductor layer 6 is of an n-type (first conductive type) conductive type. The second semiconductor layer 9 includes the n-type first light reflecting layer 10, the light generating layer 11, and the p-type (second conductive type) second light reflecting layer 12, which are laminated in this order from the first semiconductor layer 6 side. The laser diode structure 30 is partitioned in a plateau shape including the first top surface 32 by the removal portion 20 in which the second semiconductor layer 9 is dug down, and generates the laser beam.

The main surface insulating layer 50 covers the second semiconductor layer 9 and the laser diode structure 30. The main surface insulating layer 50 includes the third opening 54 that exposes the first semiconductor layer 6 in a portion that covers the bottom wall 23 of the removal portion 20. The main surface insulating layer 50 includes the second opening 52 that exposes the first top surface 32 in a portion that covers the first top surface 32. The first electrode film 61 is connected to the first semiconductor layer 6 in the third opening 54. The wiring insulating layer 142 covers at least a portion of the first electrode film 61.

The second electrode film 62 passes over the wiring insulating layer 142 so as to intersect the first electrode film 61 in a plan view, is routed over the first top surface 32 of the laser diode structure 30, and is connected to the first top surface 32 in the second opening 52. According to this structure, it is possible to form the second electrode film 62 without being restricted by the wiring rule of the first electrode film 61. Further, it is possible to form the first electrode film 61 without being restricted by the wiring rule of the second electrode film 62.

The third opening 54 may extend in a curved band shape along the laser diode structure 30 in a plan view. In this case, the first electrode film 61 may extend in a curved band shape along the third opening 54 in a plan view. According to this structure, it is possible to supply a current to the laser diode structure 30 along the circumferential direction of the laser diode structure 30. Particularly, the third opening 54 may be formed in an annular shape surrounding the laser diode structure 30 in a plan view. In this case, the first electrode film 61 may be formed in an annular shape surrounding the laser diode structure 30 along the third opening 54 in a plan view. According to this structure, it is possible to supply a current to the laser diode structure 30 from the entire area of the laser diode structure 30 in the circumferential direction.

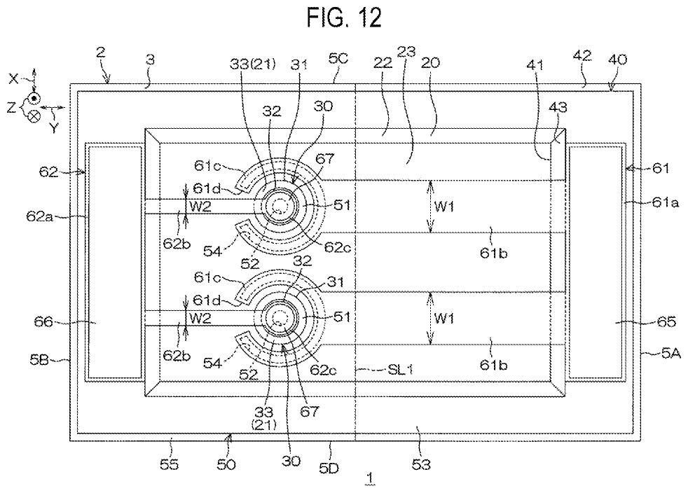

FIG. 12 is a plan view showing a modification of the surface emitting laser device 1 according to the first embodiment. FIG. 12 illustrates a modification of the surface emitting laser device 1 according to the first embodiment, but the modification according to FIG. 12 is also applied to the surface emitting laser devices 101, 111, 121, 131, and 141 according to the second to sixth embodiments. Hereinafter, structures corresponding to the structures described for the surface emitting laser device 1 are denoted by the same reference numerals, and explanation thereof will be omitted.

The surface emitting laser device 1 according to the first embodiment includes the single laser diode structure 30. However, as shown in FIG. 12, the surface emitting laser device 1 may include a plurality of laser diode structures 30. In this modification, the plurality of laser diode structures 30 are arranged so as to be adjacent to one another in the first direction X. The plurality of laser diode structures 30 may be arranged so as to be adjacent to one another in the second direction Y. Of course, the surface emitting laser device 1 may include a plurality of laser diode structures 30 arranged in a matrix, staggered, concentric, or irregular pattern at distances in the first direction X and the second direction Y.

The surface emitting laser device 1 has a plurality of second openings 52 that expose the first top surfaces 32 of the plurality of laser diode structures 30, respectively, in the second insulating layer 51 (the main surface insulating layer 50). The shape of each second opening 52 is the same as that of the first embodiment. The surface emitting laser device 1 has a plurality of third openings 54 that expose the peripheries of the plurality of laser diode structures 30, respectively, in the third insulating layer 53 (the main surface insulating layer 50). The shape of each third opening 54 is the same as that of the first embodiment.

The surface emitting laser device 1 includes a first electrode film 61 and a second electrode film 62 for connecting the plurality of laser diode structures 30 in parallel. The first electrode film 61 includes one first pad electrode film 61a, a plurality of first wiring electrode films 61b, and a plurality of first connection electrode films 61c. Each first wiring electrode film 61b is drawn out toward each laser diode structure 30 in the same manner as in the case of the first embodiment. Each first connection electrode film 61c is electrically connected to the first semiconductor layer 6 around each laser diode structure 30 in the same manner as in the case of the first embodiment, and includes an open portion 61d.

The second electrode film 62 includes one second pad electrode film 62a, a plurality of second wiring electrode films 62b, and a plurality of second connection electrode films 62c. Each second wiring electrode film 62b is drawn out toward each laser diode structure 30 in the same manner as in the case of the first embodiment. Each second connection electrode film 62c is electrically connected to the first top surface 32 of each laser diode structure 30 in the same manner as in the case of the first embodiment.

The surface emitting laser device 1 includes one first terminal electrode 65, one second terminal electrode 66, and a plurality of third terminal electrodes 67. The plurality of third terminal electrodes 67 are arranged on the plurality of second connection electrode films 62c, respectively. Of course, the surface emitting laser device 1 may include a plurality of first terminal electrodes 65 and a plurality of second terminal electrodes 66. As described above, even when the modification according to FIG. 12 is adopted, this modification can obtain the same effects as the effects described in the above-described first embodiment.

The present disclosure can be implemented in other embodiments. For example, in each of the above-described embodiments, the example in which the first semiconductor layer 6 includes the laminated structure including the n-type semiconductor substrate 7 and the n-type first contact layer 8 has been described. However, the first semiconductor layer 6 may include a single-layer structure composed of only the n-type semiconductor substrate 7. In each of the above-described embodiments, the example in which the laser diode structure 30 is formed to be deviated from the center of the second semiconductor layer 9 in a plan view has been described. However, the laser diode structure 30 may be formed at the center of the second semiconductor layer 9 in a plan view.

In the above-described first embodiment, the example in which the first to third terminal electrodes 65 to 67 are formed has been described. However, a surface emitting laser device 1 that does not have the first to third terminal electrodes 65 to 67 may be adopted. In this case, the first pad electrode film 61a, the second pad electrode film 62a, and the second connection electrode film 62c may be formed as terminal electrodes. In the above-described second and third embodiments, the example in which the third terminal electrode 67 is formed has been described. However, an embodiment in which the third terminal electrode 67 is removed from the above-described second and third embodiments may be adopted.

In the above-described second to sixth embodiments, the example in which the second insulating layer 51 including the second opening 52 having the second diameter D2 less than the first diameter D1 of the first opening 35 (D2<D1) in the region surrounded by the first opening 35 in a plan view is formed has been described. However, in the above-described second to sixth embodiments, a second insulating layer 51 including the second opening 52 having the second diameter D2 equal to or larger than the first diameter D1 of the first opening 35 (D1≤D2) in a plan view may be formed.

In other words, in the above-described second to sixth embodiments, the third inclination angle θ3 may be 0 degree or less and the distance D may be 0 μm or less. Of course, in the above-described second to sixth embodiments, the second opening 52 may have the second diameter D2 that exceeds the first diameter D1 (D1<D2) and may surround the first opening 35 in a plan view. In each of the above-described embodiments, the example in which the first conductive type is n-type and the second conductive type is p-type has been described, but the first conductive type may be p-type and the second conductive type may be n-type. The specific configuration in this case is obtained by replacing an n-type region with a p-type region and vice versa in the above description and the accompanying drawings.

Hereinafter, examples of features extracted from the present disclosure and the drawings are shown. [A1] to [A20], [B1] to [B11], [C1] to [C16], [D1] to [D5], and [E1] to [E3] shown below provide surface emitting laser devices having novel structures. Hereinafter, the alphanumeric characters in brackets represent the corresponding elements and the like in the above-described embodiments, but do not limit the scope of individual items to the embodiments.

[A1] A surface emitting laser device (1, 101, 111, 121, 131, 141) including: a first semiconductor layer (6) of a first conductive type (n-type); a second semiconductor layer (9) including a first light reflecting layer (10) of the first conductive type (n-type), a light generating layer (11), and a second light reflecting layer (12) of a second conductive type (p-type), which are laminated in this order from a first semiconductor layer (6) side; a laser diode structure (30) partitioned in a plateau shape including a top surface (32) by a removal portion (20) in which the second semiconductor layer (9) is dug down, and emits a laser beam to the first semiconductor layer (6) side; a first insulating layer (34) formed inside the laser diode structure (30), including a first opening (35) having a first diameter (D1) in a plan view, and partitions a current constriction layer (36) by the first opening (35); and a second insulating layer (51) covering the top surface (32) and including a second opening (52) having a second diameter (D2) less than the first diameter (D1) in a region surrounded by the first opening (35) in a plan view.

[A2] The surface emitting laser device (1, 101, 111, 121, 131, 141) of A1, wherein when an oblique line (L0) connecting an opening end of the first opening (35) and an opening end of the second opening (52) is set in a cross-sectional view, an angle (03) formed by the oblique line (L0) with respect to a normal direction (Z) of the top surface (32) exceeds 0 degree and is equal to or less than 45 degrees.

[A3] The surface emitting laser device (1, 101, 111, 121, 131, 141) of A1 or A2, wherein when a first straight line (L1) passing through the opening end of the first opening (35) in the normal direction (Z) of the top surface (32) and a second straight line (L2) passing through the opening end of the second opening (52) in the normal direction (Z) of the top surface (32) are set in a cross-sectional view, a distance (D) between the first straight line (L1) and the second straight line (L2) with respect to a tangential direction of the top surface (32) exceeds 0 μm and is equal to or less than 200 μm.

[A4] The surface emitting laser device (1, 101, 111, 121, 131, 141) of any one of A1 to A3, wherein the first light reflecting layer (10) has a first thickness (T1), and the second light reflecting layer (12) has a second thickness (T2) exceeding the first thickness (T1).

[A5] The surface emitting laser device (1, 101, 111, 121, 131, 141) of any one of A1 to A4, wherein the laser diode structure (30) is partitioned in a frustum-shaped plateau shape.

The surface emitting laser device (1, 101, 111, 121, 131, 141) of any one of A1 to A5, wherein the first insulating layer (34) is interposed between the top surface (32) and the light generating layer (11) inside the laser diode structure (30).

[A7] The surface emitting laser device (1, 101, 111, 121, 131, 141) of any one of A1 to A6, wherein the second semiconductor layer (9) includes a mounting surface (3) facing a connection target.

[A8] The surface emitting laser device (1, 101, 111, 121, 131, 141) of any one of A1 to A7, further including: a frame structure (40) which is partitioned in a plateau shape in a region different from the laser diode structure (30) by the removal portion (20) in the second semiconductor layer (9).

[A9] The surface emitting laser device (1, 101, 111, 121, 131, 141) of A8, wherein the frame structure (40) is formed in an electrically-floating state.

[A10] The surface emitting laser device (1, 101, 111, 121, 131, 141) of any one of A1 to A9, further including: a third insulating layer (53) covering a region outside the laser diode structure (30) in the second semiconductor layer (9) and including a third opening (54) exposing the first semiconductor layer (6); a first electrode film (61) electrically connected to the first semiconductor layer (6) in the third opening (54); and a second electrode film (62) electrically connected to the top surface (32) in the second opening (52).

[A11] The surface emitting laser device (1, 101, 111, 121, 131, 141) of A10, wherein the third insulating layer (53) covers the second semiconductor layer (9) to expose a peripheral edge portion of the second semiconductor layer (9).

[A12] The surface emitting laser device (1, 101, 111, 121, 131, 141) of A10 or A11, wherein the first electrode film (61) includes a first pad electrode film (61a) arranged on the third insulating layer (53) at a distance from the laser diode structure (30), a first wiring electrode film (61b) drawn out from the first pad electrode film (61a), and a first connection electrode film (61c) electrically connected to the first semiconductor layer (6) in the third opening (54), and wherein the second electrode film (62) includes a second pad electrode film (62a) arranged on the third insulating layer (53) at a distance from the laser diode structure (30), a second wiring electrode film (62b) drawn out from the second pad electrode film (62a), and a second connection electrode film (62c) electrically connected to the laser diode structure (30) in the second opening (52).

[A13] The surface emitting laser device (1, 101, 111, 121, 131, 141) of A12, wherein the third opening (54) extends in a curved band shape along the laser diode structure (30) in a plan view, and the first connection electrode film (61c) extends in a curved band shape along the laser diode structure (30) in a plan view.

[A14] The surface emitting laser device (1, 101, 111, 121, 131, 141) of A12 to A13, wherein the second pad electrode film (62a) faces the first pad electrode film (61a) with the laser diode structure (30) interposed therebetween in a plan view.

[A15] The surface emitting laser device (1, 101, 111, 121, 131, 141) of any one of A12 to A14, wherein the first wiring electrode film (61b) is drawn out in a straight line shape toward the laser diode structure (30), and the second wiring electrode film (62b) is drawn out in a straight line shape toward the laser diode structure (30).

[A16] The surface emitting laser device (1, 101, 111, 121, 131, 141) of A15, wherein the second wiring electrode film (62b) is located on the same straight line as the first wiring electrode film (61b) in a plan view.

[A17] The surface emitting laser device (1, 101, 111, 121, 131, 141) of any one of A12 to A16, wherein the first wiring electrode film (61b) has a first wiring width (W1), and the second wiring electrode film (62b) has a second wiring width (W2) less than the first wiring width (W1).

[A18] The surface emitting laser device (1, 101, 111, 121, 131, 141) of any one of A1 to A17, wherein the laser diode structure (30) is partitioned at a position deviated from a center of the second semiconductor layer (9) in a plan view.

[A19] The surface emitting laser device (1, 101, 111, 121, 131, 141) of any one of A1 to A18, wherein the laser diode structure is a single laser diode structure (30).

[A20] The surface emitting laser device (1, 101, 111, 121, 131, 141) of any one of A1 to A19, wherein the first semiconductor layer (6) includes a laminated structure including a semiconductor substrate (7) of the first conductive type (n-type) and a contact layer (8) of the first conductive type (n-type) having an impurity concentration higher than an impurity concentration of the semiconductor substrate (7), and wherein the second semiconductor layer (9) is formed on the contact layer (8).

[B1] A surface emitting laser device (101, 111) including: a first semiconductor layer (6) of a first conductive type (n-type); a second semiconductor layer (9) including a first light reflecting layer (10) of the first conductive type (n-type), a light generating layer (11), and a second light reflecting layer (12) of a second conductive type (p-type), which are laminated in this order from a first semiconductor layer (6) side; a laser diode structure (30) partitioned in a plateau shape including a top surface (32) and a side wall (33) on the second semiconductor layer (9) by a removal portion (20) in which the second semiconductor layer (9) is dug down, and generates a laser beam; an electrode film (62b) that covers the side wall (33); and a side wall electrode (102) that has a thickness exceeding the thickness of the electrode film (62b) and covers the electrode film (62b).

[B2] The surface emitting laser device (101, 111) of B1, wherein the second semiconductor layer (9) includes a mounting surface (3) facing a connection target, and the laser diode structure (30) emits a laser beam to the first semiconductor layer (6) side.

[B3] The surface emitting laser device (101, 111) of B1 or B2, further including: a connection electrode film (62c) that covers the top surface (32) and is electrically connected to the top surface (32), and a terminal electrode (67) that has a thickness exceeding the thickness of the connection electrode film (62c) and covers the connection electrode film (62c).

[B4] The surface emitting laser device (101, 111) of B3, wherein the side wall electrode (102) is connected to the terminal electrode (67) on the top surface (32).

[B5] The surface emitting laser device (101, 111) of any one of B1 to B4, wherein the electrode film (62b) covers the entire area of the side wall (33), and the side wall electrode (102) covers the entire area of the side wall (33) with the electrode film (62b) interposed therebetween.

[B6] The surface emitting laser device (101, 111) of any one of B1 to B5, further including: an insulating layer (50, 51) that covers the side wall (33), wherein the electrode film (62b) covers the insulating layer (50, 51).

[B7] The surface emitting laser device (101, 111) of any one of B1 to B6, further including: an internal insulating layer (34) that is formed inside the laser diode structure (30), includes a first opening (35) having a first diameter (D1) in a plan view, and partitions a current constriction layer (36) by the first opening (35), wherein the insulating layer (50, 51) covers the top surface (32) and includes a second opening (52) having a second diameter (D2) less than the first diameter (D1) in a region surrounded by the first opening (35) in a plan view.

[B8] The surface emitting laser device (101, 111) of B7, wherein when an oblique line (L0) connecting an opening end of the first opening (35) and an opening end of the second opening (52) is set in a cross-sectional view, an angle (03) formed by the oblique line (L0) with respect to the normal direction (Z) of the top surface (32) exceeds 0 degree and is equal to or less than 45 degrees.

[B9] The surface emitting laser device (101, 111) of B7 or B8, wherein when a first straight line (L1) passing through the opening end of the first opening (35) in the normal direction (Z) of the top surface (32) and a second straight line (L2) passing through the opening end of the second opening (52) in the normal direction (Z) of the top surface (32) are set in a cross-sectional view, a distance (D) between the first straight line (L1) and the second straight line (L2) with respect to the tangential direction of the top surface (32) exceeds 0 μm and is equal to or less than 200 μm.

[B10] The surface emitting laser device (101, 111) of any one of B1 to B9, wherein the first light reflecting layer (10) has a first thickness (T1), and the second light reflecting layer (12) has a second thickness (T2) exceeding the first thickness (T1).

[B11] The surface emitting laser device (101, 111) of any one of B1 to B10, wherein the laser diode structure (30) is partitioned in a frustum-shaped plateau shape.

[C1] A surface emitting laser device (121, 131) including: a first semiconductor layer (6) of a first conductive type (n-type); a second semiconductor layer (9) including a first light reflecting layer (10) of the first conductive type (n-type), a light generating layer (11), and a second light reflecting layer (12) of a second conductive type (p-type), which are laminated in this order from a first semiconductor layer (6) side; a laser diode structure (30) partitioned in a plateau shape including a first top surface (32) on the second semiconductor layer (9) by a removal portion (20) in which the second semiconductor layer (9) is dug down, and generates a laser beam; a frame structure (40) partitioned in a plateau shape including a second top surface (42) by the removal portion (20) in a region different from the laser diode structure (30) in the second semiconductor layer (9); a first terminal electrode (65) arranged on the second top surface (42); a second terminal electrode (66) arranged on the second top surface (42) at a distance from the first terminal electrode (65); and a third terminal electrode (67) that has a thickness exceeding the thickness of the first terminal electrode (65) and the thickness of the second terminal electrode (66) and is arranged on the first top surface (32).

[C2] The surface emitting laser device (121, 131) of C1, wherein the second semiconductor layer (9) includes a mounting surface (3) facing a connection target, and the laser diode structure (30) emits a laser beam to the first semiconductor layer (6) side.

[C3] The surface emitting laser device (121, 131) of C1 or C2, wherein the third terminal electrode (67) protrudes in a range of 0.5 μm or more and 10 μm or less from one or both of an electrode surface of the first terminal electrode (65) and an electrode surface of the second terminal electrode (66).

[C4] The surface emitting laser device (121, 131) of any one of C1 to C3, wherein the second terminal electrode (66) has the same thickness as the first terminal electrode (65).

[C5] The surface emitting laser device (121, 131) of any one of C1 to C4, wherein the second terminal electrode (66) faces the first terminal electrode (65) with the laser diode structure (30) interposed therebetween in a plan view.

[C6] The surface emitting laser device (121, 131) of any one of C1 to C5, wherein the third terminal electrode (67) is located on a straight line connecting the first terminal electrode (65) and the second terminal electrode (66) in a plan view.

[C7] The surface emitting laser device (121, 131) of any one of C1 to C6, wherein the frame structure (40) is formed in an electrically-floating state.

[C8] The surface emitting laser device (121, 131) of any one of C1 to C7, wherein the laser diode structure (30) is partitioned so as to be deviated from a center of the second semiconductor layer (9) in a plan view.

[C9] The surface emitting laser device (121, 131) of any one of C1 to C8, further including: a first pad electrode film (61a) that covers the second top surface (42); a second pad electrode film (62a) that covers the second top surface (42) at a distance from the first pad electrode film (61a); and a connection electrode film (62c) that covers the first top surface (32) and is electrically connected to the first top surface (32), wherein the first terminal electrode (65) is arranged on the first pad electrode film (61a), the second terminal electrode (66) is arranged on the second pad electrode film (62a), and the third terminal electrode (67) is arranged on the connection electrode film (62c).

[C10] The surface emitting laser device (121, 131) of any one of C1 to C9, wherein the first terminal electrode (65) is composed of an Au-based metal film, the second terminal electrode (66) is composed of an Au-based metal film, and the third terminal electrode (67) is composed of an Au-based metal film.

[C11] The surface emitting laser device (121, 131) of any one of C1 to C10, wherein the frame structure (40) is formed in an annular shape surrounding the laser diode structure (30) in a plan view.

[C12] The surface emitting laser device (121, 131) of any one of C1 to C11, wherein the first light reflecting layer (10) has a first thickness (T1), and the second light reflecting layer (12) has a second thickness (T2) exceeding the first thickness (T1).

[C13] The surface emitting laser device (121, 131) of any one of C1 to C12, wherein the laser diode structure (30) is partitioned in a frustum-shaped plateau shape.

[C14] The surface emitting laser device (121, 131) of any one of C1 to C13, further including: a first insulating layer (34) that is formed inside the laser diode structure (30), includes a first opening (35) having a first diameter (D1) in a plan view, and partitions a current constriction layer (36) by the first opening (35); and a second insulating layer (51) that covers the first top surface (32) and includes a second opening (52) having a second diameter (D2) less than the first diameter (D1) in a region surrounded by the first opening (35) in a plan view.

[C15] The surface emitting laser device (121, 131) of C14, wherein when an oblique line (L0) connecting an opening end of the first opening (35) and an opening end of the second opening (52) is set in a cross-sectional view, an angle (03) formed by the oblique line (L0) with respect to the normal direction (Z) of the first top surface (32) exceeds 0 degree and is equal to or less than 45 degrees.

[C16] The surface emitting laser device (121, 131) of C14 or C15, wherein when a first straight line (L1) passing through the opening end of the first opening (35) in the normal direction (Z) of the first top surface (32) and a second straight line (L2) passing through the opening end of the second opening (52) in the normal direction (Z) of the first top surface (32) are set in a cross-sectional view, a distance (D) between the first straight line (L1) and the second straight line (L2) with respect to the tangential direction of the first top surface (32) exceeds 0 μm and is equal to or less than 200 μm.

[D1] A surface emitting laser device (131) including: a first semiconductor layer (6) of a first conductive type (n-type); a second semiconductor layer (9) including a first light reflecting layer (10) of the first conductive type (n-type), a light generating layer (11), and a second light reflecting layer (12) of a second conductive type (p-type), which are laminated in this order from a first semiconductor layer (6) side; a laser diode structure (30) partitioned in a plateau shape including a first top surface (32) and a first side wall (33) on the second semiconductor layer (9) by a removal portion (20) in which the second semiconductor layer (9) is dug down; a frame structure (40) partitioned in a plateau shape including a second top surface (42) and a second side wall (43) by the removal portion (20) in a region different from the laser diode structure (30) in the second semiconductor layer (9); a first pad electrode film (61a) covering the second top surface (42); a second pad electrode film (62a) covering the second top surface (42) at a distance from the first pad electrode film (61a); an electrode film (62b) covering the first side wall (33); a connection electrode film (62c) covering the first top surface (32) and being electrically connected to the first top surface (32); a first terminal electrode (65) arranged on the first pad electrode film (61a); a second terminal electrode (66) arranged on the second pad electrode film (62a); a third terminal electrode (67) having a thickness exceeding the thickness of the first terminal electrode (65) and the thickness of the second terminal electrode (66) and being arranged on the connection electrode film (62c); and a side wall electrode (102) having a thickness exceeding the thickness of the electrode film (62b) and covering the electrode film (62b).

[D2] The surface emitting laser device (131) of D1, wherein the second semiconductor layer (9) includes a mounting surface (3) facing a connection target, and the laser diode structure (30) emits a laser beam to the first semiconductor layer (6) side.

[D3] The surface emitting laser device (131) of D1 or D2, wherein the first terminal electrode (65) has a thickness exceeding the thickness of the first pad electrode film (61a), and the second terminal electrode (66) has a thickness exceeding the thickness of the second pad electrode film (62a).

[D4] The surface emitting laser device (131) of any one of D1 to D3, wherein the side wall electrode (102) is connected to the third terminal electrode (67) on the first top surface (32).

[D5] The surface emitting laser device (131) of any one of D1 to D4, wherein the electrode film (62b) covers the entire area of the first side wall (33), and the side wall electrode (102) covers the entire area of the first side wall (33) with the electrode film (62b) interposed therebetween.

[E1] A surface emitting laser device (141) including: a first semiconductor layer (6) of a first conductive type (n-type); a second semiconductor layer (9) including a first light reflecting layer (10) of the first conductive type (n-type), a light generating layer (11), and a second light reflecting layer (12) of a second conductive type (p-type), which are laminated in this order from a first semiconductor layer (6) side; a laser diode structure (30) partitioned in a plateau shape including a top surface (32) by a removal portion (20) in which the second semiconductor layer (9) is dug down, and emitting a laser beam to the first semiconductor layer (6) side; a main surface insulating layer (50) covering the second semiconductor layer (9) and the laser diode structure (30) and including a first contact opening (54) that exposes the first semiconductor layer (6) to a portion covering a bottom wall (23) of the removal portion (20), and a second contact opening (52) that exposes the top surface (32) to a portion covering the top surface (32); a first electrode film (61) connected to the first semiconductor layer (6) in the first contact opening (54); an insulating layer (142) covering at least a portion of the first electrode film (61); and a second electrode film (62) that passes over the insulating layer (142) so as to intersect the first electrode film in a plan view, is routed over the top surface (32) of the laser diode structure (30), and is connected to the top surface (32) in the second contact opening (52).

[E2] The surface emitting laser device (141) of E1, wherein the first contact opening (54) extends in a curved band shape along the laser diode structure (30) in a plan view, and the first electrode film (61) extends in a curved band shape along the first contact opening (54) in a plan view.

[E3] The surface emitting laser device (141) of E1 or E2, wherein the first contact opening (54) is formed in an annular shape surrounding the laser diode structure (30) in a plan view, and the first electrode film (61) is formed in an annular shape surrounding the laser diode structure (30) along the first contact opening (54) in a plan view.

Although the embodiments of the present disclosure have been described in detail, these embodiments are merely specific examples used for clarifying the technical contents of the present disclosure, the present disclosure should not be construed as being limited to these specific examples, and the scope of the present disclosure is limited by the accompanying claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A surface emitting laser device comprising:
a first semiconductor layer of a first conductive type;
a second semiconductor layer including a first light reflecting layer of the first conductive type, a light generating layer, and a second light reflecting layer of a second conductive type, which are laminated in this order from a first semiconductor layer side;
a laser diode structure partitioned in a plateau shape including a top surface by a removal portion in which the second semiconductor layer is dug down, and configured to emit a laser beam to the first semiconductor layer side;
a first insulating layer formed inside the laser diode structure, including a first opening having a first diameter in a plan view, and partitioning a current constriction layer by the first opening; and
a second insulating layer covering the top surface and including a second opening having a second diameter less than the first diameter in a region surrounded by the first opening in a plan view.

2. The surface emitting laser device of claim 1, wherein when an oblique line connecting an opening end of the first opening and an opening end of the second opening is set in a cross-sectional view, an angle formed by the oblique line with respect to a normal direction of the top surface exceeds 0 degree and is equal to or less than 45 degrees.

3. The surface emitting laser device of claim 1, wherein when a first straight line passing through an opening end of the first opening in a normal direction of the top surface and a second straight line passing through an opening end of the second opening in the normal direction of the top surface are set in a cross-sectional view, a distance between the first straight line and the second straight line with respect to a tangential direction of the top surface exceeds 0 μm and is equal to or less than 200 μm.

4. The surface emitting laser device of claim 1, wherein the first light reflecting layer has a first thickness, and the second light reflecting layer has a second thickness exceeding the first thickness.

5. The surface emitting laser device of claim 1, wherein the laser diode structure is partitioned in a frustum-shaped plateau shape.

6. The surface emitting laser device of claim 1, wherein the first insulating layer is interposed between the top surface and the light generating layer inside the laser diode structure.

7. The surface emitting laser device of claim 1, wherein the second semiconductor layer includes a mounting surface facing a connection target.

8. The surface emitting laser device of claim 1, further comprising: a frame structure which is partitioned in a plateau shape in a region different from the laser diode structure by the removal portion in the second semiconductor layer.

9. The surface emitting laser device of claim 8, wherein the frame structure is formed in an electrically-floating state.

10. The surface emitting laser device of claim 1, further comprising:
a third insulating layer covering a region outside the laser diode structure in the second semiconductor layer and including a third opening exposing the first semiconductor layer;
a first electrode film electrically connected to the first semiconductor layer in the third opening; and
a second electrode film electrically connected to the top surface in the second opening.

11. The surface emitting laser device of claim 10, wherein the third insulating layer covers the second semiconductor layer so as to expose a peripheral edge portion of the second semiconductor layer.

12. The surface emitting laser device of claim 10, wherein the first electrode film includes a first pad electrode film arranged on the third insulating layer at a distance from the laser diode structure, a first wiring electrode film drawn out from the first pad electrode film, and a first connection electrode film electrically connected to the first semiconductor layer in the third opening, and
wherein the second electrode film includes a second pad electrode film arranged on the third insulating layer at a distance from the laser diode structure, a second wiring electrode film drawn out from the second pad electrode film, and a second connection electrode film electrically connected to the laser diode structure in the second opening.

13. The surface emitting laser device of claim 12, wherein the third opening extends in a curved band shape along the laser diode structure in a plan view, and the first connection electrode film extends in a curved band shape along the laser diode structure in a plan view.

14. The surface emitting laser device of claim 12, wherein the second pad electrode film faces the first pad electrode film with the laser diode structure interposed therebetween in a plan view.

15. The surface emitting laser device of claim 12, wherein the first wiring electrode film is drawn out in a straight line shape toward the laser diode structure, and the second wiring electrode film is drawn out in a straight line shape toward the laser diode structure.

16. The surface emitting laser device of claim 15, wherein the second wiring electrode film is located on the same straight line as the first wiring electrode film in a plan view.

17. The surface emitting laser device of claim 12, wherein the first wiring electrode film has a first wiring width, and the second wiring electrode film has a second wiring width less than the first wiring width.

18. The surface emitting laser device of claim 1, wherein the laser diode structure is partitioned at a position deviated from a center of the second semiconductor layer in a plan view.

19. The surface emitting laser device of claim 1, wherein the laser diode structure is a single laser diode structure.

20. The surface emitting laser device of claim 1, wherein the first semiconductor layer includes a laminated structure including a semiconductor substrate of the first conductive type and a contact layer of the first conductive type having an impurity concentration higher than an impurity concentration of the semiconductor substrate, and
wherein the second semiconductor layer is formed on the contact layer.
